(19) United States
(12) Patent Application Publication
(10) Pub. No.: US 2006/0049716 A1
(43) Pub. Date: Mar. 9, 2006

(54) Drive unit

(75) Inventor: Tomoyuki Yuasa, Sakai-shi (JP)

Correspondence Address: SIDLEY AUSTIN BROWN & WOOD LLP, 717 NORTH HARWOOD, SUITE 3400, DALLAS, TX, 75201, US

(73) Assignee: KONICA MINOLTA OPTO, INC.

(21) Appl. No.: 11/221,061

(22) Filed: Sep. 7, 2005

(30) Foreign Application Priority Data
Sep. 9, 2004 (JP) 2004-261954

(51) Int. Cl. H01L 41/09

(52) U.S. Cl. 310/317

(57) ABSTRACT

A drive unit allowing ultraprecise positioning control of a movable member is provided. A drive unit includes an piezoelectric element which expands and contracts upon application of a voltage, a drive shaft fixed to one end of the piezoelectric element along expansion and contraction direction, a movable member which engages with the drive shaft by friction force and is driven along the drive shaft which is oscillated by the expanding and contracting piezoelectric element, and a drive circuit for applying a voltage to the piezoelectric element, in which the drive circuit changes a waveform of the voltage applied to the piezoelectric element so that the movable member is switched between high-speed drive and low-speed drive.

### RELATED APPLICATION

This application is based on Japanese Patent Application No. 2004-261954, the content of which is incorporated herein by reference.

### BACKGROUND OF THE INVENTION

The present invention relates to a drive unit utilizing an electromechanical conversion element such as piezoelectric elements, and more particularly relates to a drive unit suitable, for example, for precision drive of XY stages and precision drive of camera lenses.

Conventionally, for example in JP 2000-350482 A, a drive unit 1 has been disclosed as shown in FIG. 1. In the drive unit 1, a piezoelectric element (electromechanical conversion element) 2 and serially-connected four FETs (Field-Effect Transistors) 4, 6, 8, 10 constitute a bridge circuit, and the bases of the respective FETs 4, 6, 8, 10 have signal inputs from a control circuit 12. Moreover, a power supply 14 is connected to between the FETs 4 and 6, and a ground is disposed in between the FETs 8 and 10. The four FETs 4, 6, 8, 10, the control circuit 12 and the power supply 14 constitute a drive circuit 3.

Among the four FETs 4, 6, 8, 10, the FETs 4, 6 are P channel-type FETs, which are isolated when a signal inputted from the control circuit 12 to each base is at high level and which are put into conduction when the signal is at low level. Contrary to this, among the four FETs 4, 6, 8, 10, the FET 8, 10 are N channel-type FETs, which are put into conduction when a signal inputted from the control circuit 12 to each base is at high level and which is isolated when the signal is at low level.

FIG. 2 is a timing chart presenting an operation sequence of the drive unit 1 for showing gate voltages of the respective FETs 4, 6, 8, 10 and a drive voltage applied to the piezoelectric element 2. In a period 1 in FIG. 2, the P channel-type FET 6 is blocked upon input of a high signal H(V) into the gate, the N channel-type FET 10 is put into conduction upon input of a high signal H(V) into the gate, the P channel-type FET 4 is put into conduction upon input of a low signal L(V) into the gate, and the N channel-type FET 8 is blocked upon input of a low signal L(V) into the gate. In this case, through the FETs 4, 10 in conduction state, a drive voltage +E(V) is applied from the power supply 14 to the piezoelectric element 2.

In a period 2 in FIG. 2, the P channel-type FET 6 is put into conduction upon input of a low signal L(V) into the gate, the N channel-type FET 10 is blocked upon input of a low signal L(V) into the gate, the P channel-type FET 4 is blocked upon input of a high signal H(V) into the gate, and the N channel-type FET 8 is put into conduction upon input of a high signal H(V) into the gate. In this case, through the FETs 6, 8 in conduction state, a drive voltage −E(V) is applied from the power supply 14 to the piezoelectric element 2.

Thus, by alternate repetition of the period 1 and the period 2 in FIG. 2, an alternating voltage having an amplitude 2 E(V) which is twice as large as a power supply voltage E(V) is applied to the piezoelectric element 2.

FIG. 3 is a view showing the operation principle of the drive unit 1. The one end of the piezoelectric element 2 along expansion and contraction direction is fixed to a support member 16. The other end of the piezoelectric element 2 along expansion and contraction direction is fixed to, for example, a round bar-shaped drive shaft (drive friction member) 18. On the drive shaft 18, a movable member 20 is held movably. The movable member 20 engages with the drive shaft 18 by specified friction force generated by biasing force of an elastic member in an unshown plate spring or coil spring. An unshown lens or other driving targets are mounted on the movable member 20. Moreover, the position of the movable member 20 is detected by a position sensor 22.

FIG. 4 shows shaft displacement of the drive shaft 18 when a drive voltage with a rectangular pulse waveform as shown in FIG. 2 is applied to the actuator 1. The shaft displacement shows a sawtooth pattern having mild rising parts and rapid trailing parts, and each of states A, B and C corresponds to the states A, B and C in FIG. 3, respectively. Assuming that the state A is an initial state, the drive shaft 18 and the movable member 20 which comes into friction engagement with the drive shaft 18 are displaced to the state B at relatively mild speed when the piezoelectric element 2 expands slowly. Next, when the piezoelectric element 2 rapidly contracts, the drive shaft 18 returns to the original position at relatively high speed, which causes slippage between the movable member 20 and the drive shaft 18, thereby bringing the movable member 20 into the state C where the movable member 20 is slightly back toward the original position. In the state C, the position of the movable member 20 is slightly displaced from the state A that is the initial state in forward direction (i.e., the direction away from the piezoelectric element 2). By repeating such expansion and contraction of the piezoelectric element 2, the movable member 20 is driven in forward direction along the drive shaft 18.

Based on the principle opposite to the above description, the movable member 20 is driven in backward direction (i.e., the direction toward the piezoelectric element 2) along the drive shaft 18. More particularly, when the piezoelectric element 2 repeats rapid expansion and slow contraction, the displacement of the drive shaft 18 shows a sawtooth pattern having rapid rising parts and mild trailing parts contrary to the pattern shown in FIG. 4. Consequently, when the piezoelectric element 2 rapidly expands, the movable member 20 gains slippage against the drive shaft 18, whereas when the piezoelectric element 2 slowly contracts, the movable member 20 is slightly displaced in backward direction, and repetition of these operations moves the movable member 20 in backward direction.

FIG. 5 shows the relation between the speed of the drive shaft 18 and the frequency transmission characteristics of an inputted voltage into the piezoelectric element 2. When the frequency of the inputted voltage into the piezoelectric element 2 is relatively low, the speed of the drive shaft 18 increases in proportional to the frequency, staying high at a primary resonance frequency f1 and a secondary resonance frequency f2, and when the frequency becomes higher than the secondary resonance frequency f2, the speed tends to decrease. In order to obtain a sawtooth pattern-displacement of the drive shaft 18 as shown in FIG. 4 by inputting a drive voltage with the rectangular pulse waveform shown in FIG. 2 into the piezoelectric element 2, a frequency fd of the drive voltage should be set 0.7 times as large as the primary resonance frequency f1, and in the case of driving the movable member 20 in forward direction, a duty ratio of the drive voltage should be set at 0.3 (0.7 for driving the movable member 20 in backward direction). This has been described in JP 2001-211669 A according to another patent application by the applicant of the present invention.

The above-stated prior art is to realize high-speed drive of the movable member 20 in the drive unit 1 with a simplified drive circuit 3. However, in the case where it is desired to move the movable member 20 in the drive unit 1 for a very small distance, for example, not more than 1 μm, decreasing the frequency of the rectangular pulse voltage to reduce the number of pulses inputted into the piezoelectric element 2 leads to failure in obtaining the sawtooth displacement of the drive shaft 18 as shown in FIG. 4, which makes the behavior of the movable member 20 extremely unstable. Moreover, in driving with the above-stated rectangular pulse voltage, a certain number or more rectangular pulses is needed to gain a linear relation between the pulse number and the movement amount of the movable member 20. Because of these reasons, ultraprecise positioning control of the movable member 20 was difficult in the drive unit 1.

### SUMMARY OF THE INVENTION

An object of the present invention is to provide a drive unit in which the waveform of a drive voltage is changed to switch a movable member from high-speed drive to low-speed drive for realizing ultraprecise positioning control of the movable member.

In order to accomplish the object, the drive unit of the present invention includes:

an electromechanical conversion element which expands and contracts upon application of a voltage;

a drive friction member fixed to one end of the electromechanical conversion element along expansion and contraction direction;

a movable member which engages with the drive friction member by friction force and is driven along the drive friction member which is oscillated by the expanding and contracting electromechanical conversion element; and

a drive circuit for applying a voltage to the electromechanical conversion element, wherein

the drive circuit changes a waveform of the voltage applied to the electromechanical conversion element so that the movable member is switched between high-speed drive and low-speed drive.

In the drive unit of the present invention, it is preferable that the voltage waveform during high-speed drive of the movable member is a rectangular pulse waveform, while the voltage waveform during low-speed drive of the movable member is a step-like pulse waveform.

Moreover, in the drive unit of the present invention, the voltage during the low-speed drive of the movable member should preferably be lower in frequency than the voltage during the high-speed drive of the movable member.

Further in the unit drive in the present invention, timing of the switch between the high-speed drive and low-speed drive of the movable member may be determined based on an output of a position sensor for sensing a position of the movable member.

According to the drive unit of the present invention, the movable member is switched from high-speed drive to low-speed drive by changing the waveform of a voltage applied to the electromechanical conversion element, which allows the movable member to be stopped precisely at a desired position, thereby realizing ultraprecise positioning control of the movable member.

Moreover, even in the case where the movement amount of the movable member to a desired stop position is large, the movable member can be driven at high speed to the vicinity of the desired stop position, and therefore not very long time is necessary even for ultraprecise positioning control of the movable member.

Further, change of the voltage waveform can be achieved by a simple drive circuit having the identical configuration to the prior art, and therefore complication of the drive circuit or cost increase do not occur.

### BRIEF DESCRIPTION OF THE DRAWINGS

The present invention will be further described with reference to the accompanying drawings wherein like reference numerals refer to like parts in the several views, and wherein:

FIG. 1 is a diagram for showing a configuration of a drive unit in a conventional example and in the present embodiment;

FIG. 2 is a timing chart for showing the operation sequence in creating a drive voltage having a rectangular pulse waveform in the drive unit in FIG. 1;

FIG. 3 is an schematic view for showing a drive portion of the drive unit in FIG. 1;

FIG. 4 is a view for showing the displacement of a drive shaft in relation to time;

FIG. 5 is a view for showing relation between drive shaft speed and frequency transmission characteristics of a piezoelectric element inputted voltage;

FIG. 6 is a view for showing the timing to switch from high-speed drive to low-speed drive;

FIGS. 7A-7F are timing charts for showing the operation sequence in creating a drive voltage with a step-like pulse waveform in the drive unit in FIG. 1; and

FIGS. 8A and 8B are graph views for showing specific examples of high-speed drive and low-speed drive performed with use of the drive unit in FIG. 1.

### DETAILED DESCRIPTION OF THE PREFERRED EMBODIMENT

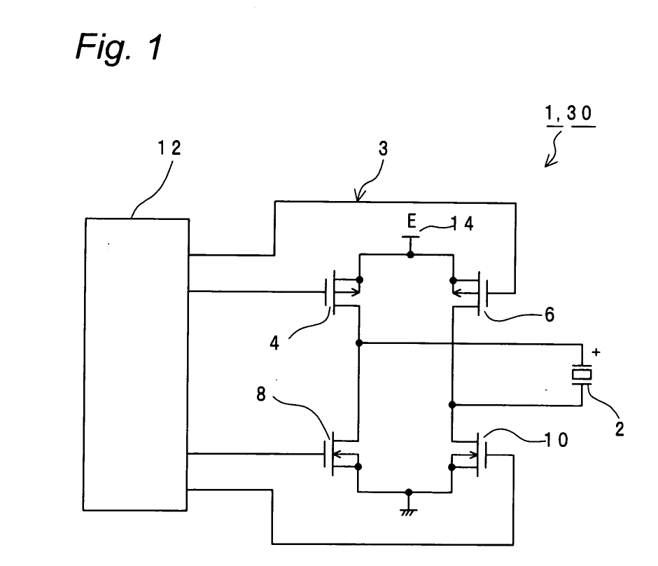

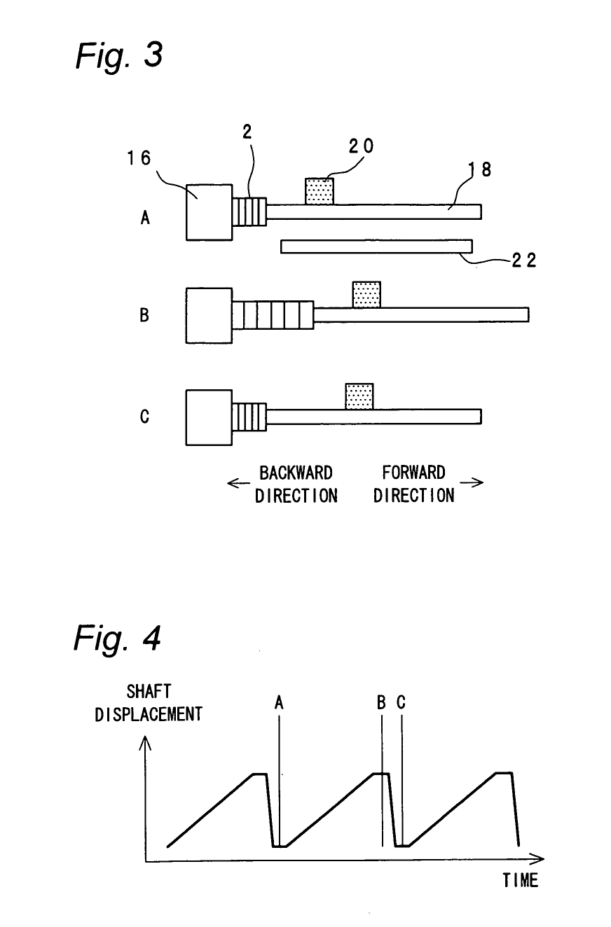

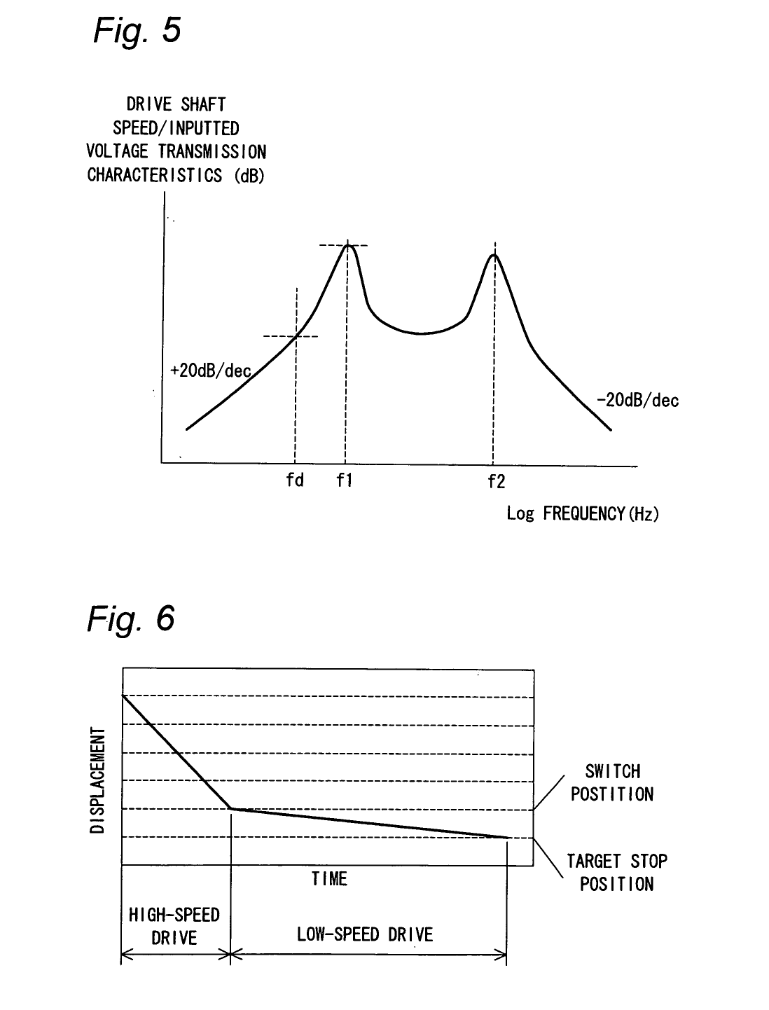

As shown in FIG. 1, a drive unit 30 in one embodiment of the present invention has a circuitry totally identical to that of the drive unit 1 described as the prior art and its drive portion is totally identical to that shown in FIG. 3. Therefore, like component members are designated by like reference numerals, and detailed description is omitted herein.

Description is now given of the operation of the drive unit 30 in the present embodiment.

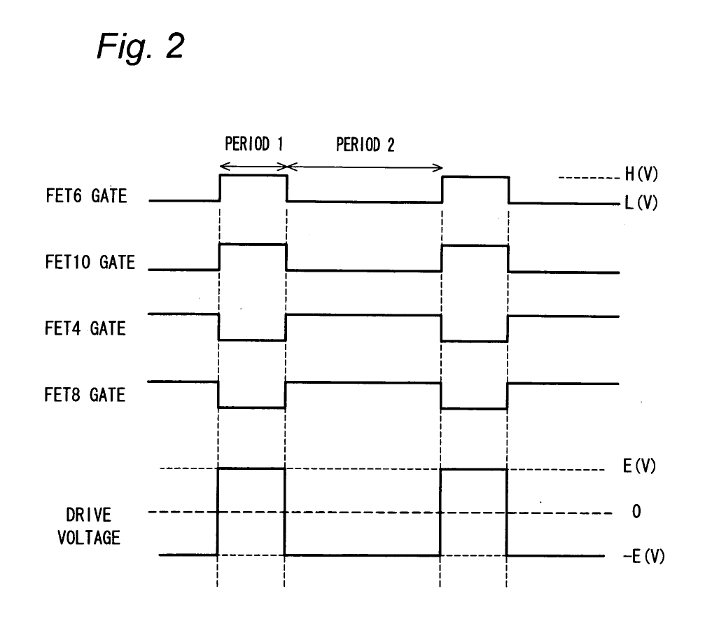

During high-speed drive of a movable member 20, a drive circuit 3 applies a rectangular pulse voltage to a piezoelectric element 2 in the same manner as the drive unit 1 described with reference to FIG. 2. More particularly, in a period 1 in FIG. 2, a P channel-type FET 6 is blocked upon input of a high signal H(V) into the gate, an N channel-type FET 10 is put into conduction upon input of a high signal H(V) into the gate, a P channel-type FET 4 is put into conduction upon input of a low signal L(V) into the gate, and an N channel-type FET 8 is blocked upon input of a low signal L(V) into the gate. In this case, through the FETs 4, 10 in conduction state, a drive voltage E is applied from a power supply 14 to the piezoelectric element 2.

In a period 2 in FIG. 2, the P channel-type FET 6 is put into conduction upon input of a low signal L(V) into the gate, the N channel-type FET 10 is blocked upon input of a low signal L(V) into the gate, the P channel-type FET 4 is blocked upon input of a high signal H(V) into the gate, and the N channel-type FET 8 is put into conduction upon input of a high signal H(V) into the gate. In this case, through the FETs 6, 8 in conduction state, a drive voltage −E is applied from the power supply 14 to the piezoelectric element 2.

Thus, by alternate repetition of the period 1 and the period 2 in FIG. 2, a drive voltage with a rectangular pulse waveform having an amplitude 2 E(V) which is twice as large as a power supply voltage E(V) is applied to the piezoelectric element 2. The drive voltage herein has a frequency 0.7 times larger than the primary resonance frequency of the piezoelectric element 2, and the duty ratio is set at 0.3 in the case of driving in forward direction. Consequently, expansive and contractive oscillation of the piezoelectric element 2 makes it possible to offer sawtooth displacement of the drive shaft 18 as shown in FIG. 4, and as a result, the movable member 20 is driven at high speed in forward direction.

In the case of driving the movable member 20 in backward direction, the drive voltage applied to the piezoelectric element 2 is set to have a frequency 0.7 time larger than the primary resonance frequency of the piezoelectric element 2 and a duty ratio of 0.7. Consequently, expansive and contractive oscillation of the piezoelectric element 2 enables the drive shaft 18 to have sawtooth displacement having rapid rising parts and mild tailing parts, which is opposite to the sawtooth displacement shown in FIG. 4. As a result, the movable member 20 is driven at high speed in backward direction.

As shown in FIG. 6, once it is detected based on an output from the position sensor 22 that the movable member 20 which has been driven at high speed as described above reaches a switch position which is a specified distance (e.g., 1 μm) short of a target stop position, the control circuit 12 changes the waveform of the drive voltage to a step-like pulse waveform for switching the movable member 20 to the low-speed drive. The step-like pulse waveform is lower in frequency than the rectangular pulse voltage during high-speed drive.

Although in the present embodiment, the timing to switch the movable member 20 from high-speed drive to low-speed drive is determined based on the output from the position sensor 22, it is also acceptable, in the case of using the drive unit 30 in the present embodiment for driving lenses of digital cameras, to determine that the movable member 20 reaches a specified switch position based on, for example, the contrast of a subject image obtained by an image pickup device such as CCDs for determining the timing to switch the movable member 20 from high-speed drive to low-speed drive.

The drive voltage having the step-like pulse waveform is created as shown below.

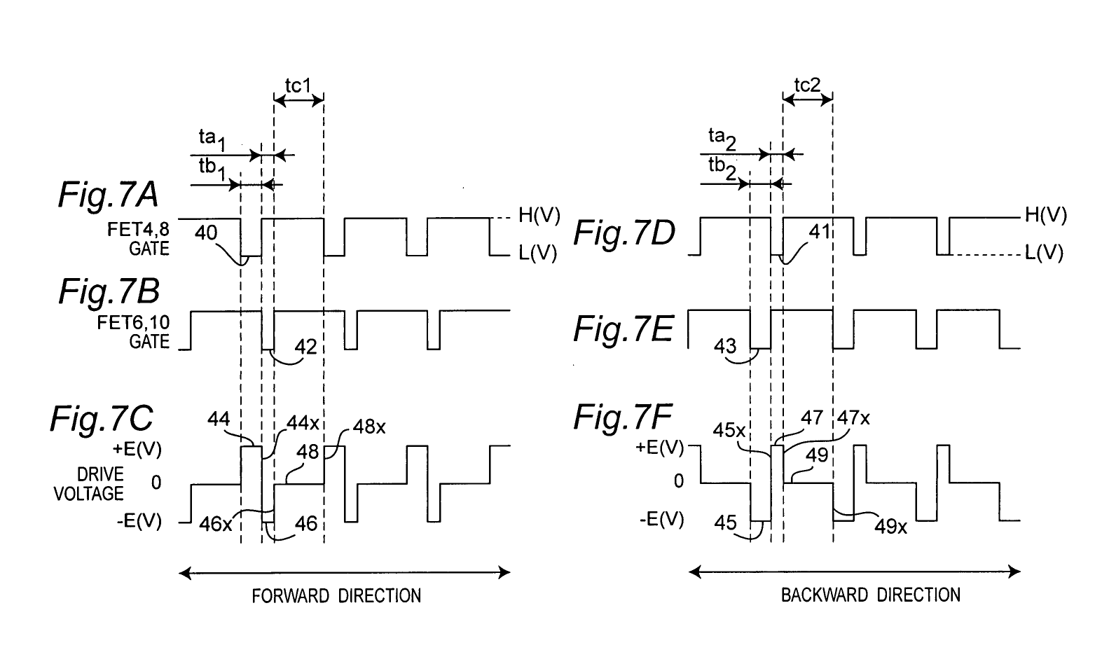

FIGS. 7A to 7C show the cases in which driving is made in forward direction.

In a first period tb₁, as denoted by reference numeral 40 in FIG. 7A, the P channel-type FET 4 is put into conduction upon input of a low signal L(V) into the gate, and the N channel-type FET 8 is blocked upon input of a low signal L(V) into the gate, while as shown in FIG. 7B, the P channel-type FET 6 is blocked upon input of a high signal H(V) into the gate, and the N channel-type FET 10 is put into conduction upon input of a high signal H(V) into the gate. In this case, through the FETs 4, 10 in conduction state, a drive voltage +E(V) is applied from the power supply 14 to the piezoelectric element 2 as shown by reference numeral 44 in FIG. 7C.

In a second period ta₁, as shown in FIG. 7A, the P channel-type FET 4 is blocked upon input of a high signal H(V) into the gate, and the N channel-type FET 8 is put into conduction upon input of a high signal H(V) into the gate, while as denoted by reference numeral 42 in FIG. 7B, the P channel-type FET 6 is put into conduction upon input of a low signal L(V) into the gate, and the N channel-type FET 10 is blocked upon input of a low signal L(V) into the gate. In this case, through the FETs 6, 8 in conduction state, a drive voltage −E(V) is applied from the power supply 14 to the piezoelectric element 2 as shown by reference numeral 46 in FIG. 7C.

In a third period tc₁, as shown in FIG. 7A, the P channel-type FET 4 is blocked upon continuous input of a high signal H(V) into the gate, and the N channel-type FET 8 is put into conduction upon continuous input of a high signal H(V) into the gate, while as shown in FIG. 7B, the P channel-type FET 6 is blocked upon input of a high signal H(V) into the gate, and the N channel-type FET 10 is put into conduction upon input of a high signal H(V) into the gate. In this case, through the FETs 8, 10 in conduction state, both the ends of the piezoelectric element 2 are short-circuited and grounded, so that the drive voltage becomes 0(V) as shown by reference numeral 48 in FIG. 7C.

Thus, by repetition of the first period tb₁, the second period ta₁ and the third period tc₁, the drive voltage is formed into a step-like pulse waveform which takes voltage values of −E(V), 0(V) and +E(V) in sequence as shown in FIG. 7C.

The movable member 20 is displaced along with the drive shaft 18 in forward direction at two relatively-small rising parts 46x and 48x in one cycle of the drive voltage. Then, at a relatively large rising part 44x of the drive voltage, the drive shaft 18 is rapidly displaced in backward direction, at the moment of which the movable member 20 remains almost in situ. By repetition of this movement, the movable member 20 is driven in forward direction along the drive shaft 18 at low speed.

FIGS. 7D to 7F show the case of driving in backward direction.

In a first period tb₂, as shown in FIG. 7D, the P channel-type FET 4 is blocked upon input of a high signal H(V) into the gate, and the N channel-type FET 8 is put into conduction upon input of a high signal H(V) into the gate, while as denoted by reference numeral 43 in FIG. 7E, the P channel-type FET 6 is put into conduction upon input of a low signal L(V) into the gate, and the N channel-type FET 10 is blocked upon input of a low signal L(V) into the gate. In this case, through the FETs 6, 8 in conduction state, a drive voltage −E(V) is applied from the power supply 14 to the piezoelectric element 2 as shown by reference numeral 45 in FIG. 7F.

In a second period ta₂, as denoted by reference numeral 41 in FIG. 7D, the P channel-type FET 4 is put into conduction upon input of a low signal L(V) into the gate, and the N channel-type FET 8 is blocked upon input of a low signal L(V) into the gate, while as shown in FIG. 7E, the P channel-type FET 6 is blocked upon input of a high signal H(V) into the gate, and the N channel-type FET 10 is put into conduction upon input of a high signal H(V) into the gate. In this case, through the FETs 4, 10 in conduction state, a drive voltage +E(V) is applied from the power supply 14 to the piezoelectric element 2 as shown by reference numeral 47 in FIG. 7F.

In a third period tc₂, as shown in FIG. 7D, the P channel-type FET 4 is blocked upon input of a high signal H(V) into the gate, and the N channel-type FET 8 is put into conduction upon input of a high signal H(V) into the gate, while as shown in FIG. 7E, the P channel-type FET 6 is blocked upon continuous input of a high signal H(V) into the gate, and the N channel-type FET 10 is put into conduction upon continuous input of a high signal H(V) into the gate. In this case, through the FETs 8, 10 in conduction state, both the ends of the piezoelectric element 2 are short-circuited and grounded, so that the drive voltage becomes 0(V) as shown by reference numeral 49 in FIG. 7F.

Thus, by repetition of the first period tb₂, the second period ta₂ and the third period tc₂, the drive voltage is formed into a step-like pulse waveform which takes voltage values of +E(V), 0(V) and −E(V) in sequence as shown in FIG. 7F.

The movable member 20 is displaced along with the drive shaft 18 in backward direction at two relatively-small rising parts 47x and 49x in one cycle of the drive voltage. Then, at a relatively large rising part 45x of the drive voltage, the drive shaft 18 is rapidly displaced in forward direction, at the moment of which the movable member 20 remains almost in situ. By repetition of this movement, the movable member 20 is driven in backward direction along the drive shaft 18 at low speed.

Thus, according to the drive unit 30 in the present embodiment, the waveform of a voltage applied to the piezoelectric element 2 is changed so as to switch the movable member 20 from high-speed drive to low-speed drive, which makes it possible to stop the movable member 20 precisely at a desired position, thereby realizing ultraprecise positioning control of the movable member 20.

Moreover, even in the case where the movement amount of the movable member 20 to a desired stop position is large, the movable member 20 can be driven at high speed to the vicinity of the desired stop position, and therefore not very long time is necessary even for ultraprecise positioning control of the movable member 20.

Further, change of the voltage waveform can be achieved by simple drive circuits 3 having identical configuration to the prior art, and therefore complication of the drive circuit or cost increase do not occur.

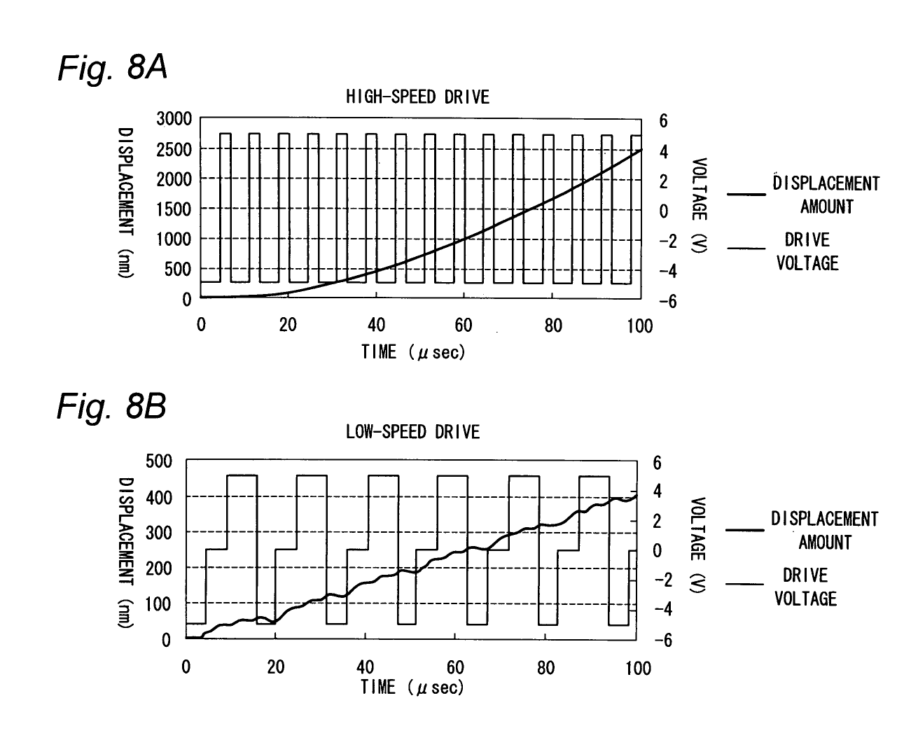

FIGS. 8A and 8B are graph views showing specific examples of high-speed drive and low-speed drive performed with use of the drive unit 30 in the present embodiment, in which FIG. 8A shows the case of the high-speed drive whereas FIG. 8B shows the case of the low-speed drive.

The drive voltage during high-speed drive is a rectangular pulse voltage alternately taking values of 5V and +5V with a frequency of 150 Hz and a duty ratio of 0.3. In this case, with a displacement amount of 1500 nm (=1.5 μm) or less, the relation between the pulse number and the displacement is not linear, indicating that precise control of the movable member 20 is not possible in very small distance drive of 1500 nm or less. Moreover, although with the displacement amount of the movable member being more than 1500 nm, the relation between the pulse number and the displacement becomes linear, the displacement amount per pulse is approx. 250 nm, which indicates that positioning control with precision of 250 nm or less cannot be achieved.

The drive voltage during low-speed drive is a step-like pulse voltage sequentially taking values of −5V, 0V and 5V with a frequency of 60 Hz. In this case, the relation with the displacement becomes almost linear from the beginning of the first pulse, and the displacement amount per pulse is as extremely small as approx. 60 nm, which indicates that the movable member 20 can be stopped precisely at a desired position, thereby realizing ultraprecise positioning control of the movable member 20.

Although in this embodiment, description has been given of the case where the movable member 20 is switched from high-speed drive to low-speed drive, it is also possible to apply the reverse method of the embodiment so that at the start of driving the movable member 20, the movable member 20 is started by low-speed drive and then is switched to high-speed drive.

Further, without being limited to element fixed-type drive units in which electromechanical conversion elements are fixed, the present invention is widely applicable to drive units of various types with use of electromechanical conversion elements including those with the movable member being fixed, the drive friction member being fixed to the support member, as well as self-propelled types.

Although the present invention has been fully described by way of examples with reference to the accompanying drawings, it is to be noted that various changes and modifications will be apparent to those skilled in the art. Therefore, unless otherwise such changes and modifications depart from the scope of the present invention, they should be construed as being included therein.

What is claimed is:

1. A drive unit, comprising:
an electromechanical conversion element which expands and contracts upon application of a voltage;
a drive friction member fixed to one end of the electromechanical conversion element along expansion and contraction direction;
a movable member which engages with the drive friction member by friction force and is driven along the drive friction member which is oscillated by the expanding and contracting electromechanical conversion element; and
a drive circuit for applying a voltage to the electromechanical conversion element, wherein
the drive circuit changes a waveform of the voltage applied to the electromechanical conversion element so that the movable member is switched between high-speed drive and low-speed drive.

2. The drive unit as defined in claim 1, wherein a voltage waveform during the high-speed drive of the movable member is a rectangular pulse waveform while a voltage waveform during the low-speed drive of the movable member is a step-like pulse waveform.

3. The drive unit as defined in claim 2, wherein a step number of the step-like pulse waveform is not greater than three.

4. The drive unit as defined in claim 2, wherein a voltage during low-speed drive of the movable member is lower in frequency than a voltage during high-speed drive of the movable member.

5. The drive unit as defined in claim 2, wherein voltage values during low-speed drive of the movable member are E and −E while voltage values during high-speed drive of the movable member are E, 0 and −E.

6. The drive unit as defined in any one of claim 1 through claim 3, wherein timing of the switch between the high-speed drive and low-speed drive of the movable member is determined based on an output of a position sensor for detecting a position of the movable member.

7. The drive unit as defined in claim 6, wherein the movable member is switched from high-speed drive to low-speed drive before the movable member stops.

8. A drive unit, comprising:
an electromechanical conversion element which expands and contracts upon application of a voltage;
a drive friction member fixed to one end of the electromechanical conversion element along expansion and contraction direction;
a movable member which engages with the drive friction member by friction force and is driven along the drive friction member which is oscillated by the expanding and contracting electromechanical conversion element; and
a drive circuit for applying a voltage to the electromechanical conversion element, wherein
the drive circuit which includes a power supply and a bridge circuit generates a first pulse waveform having a level of voltage two times a voltage of the power supply and a second pulse waveform having a level of voltage equal to a voltage of the power supply to apply the first and second pulse waveforms in combination to the electromechanical conversion element.
